(19) United States
(12) Patent Application Publication
(10) Pub. No.: US 2022/0172931 A1
(43) Pub. Date: Jun. 2, 2022

(54) Method of Processing an Etching Machine

(71) Applicant: CHANGXIN MEMORY TECHNOLOGIES, INC., Hefei City (CN)

(72) Inventors: JengYan KAO, Hefei (CN); Kai PAN, Hefei (CN); Jianfei LU, Hefei (CN); Chien Chung WANG, Hefei (CN)

(73) Assignee: CHANGXIN MEMORY TECHNOLOGIES, INC., Hefei City (CN)

(21) Appl. No.: 17/459,185

(22) Filed: Aug. 27, 2021

Related U.S. Application Data
(63) Continuation of application No. PCT/CN2021/096156, filed on May 26, 2021.

(30) Foreign Application Priority Data
Nov. 27, 2020 (CN) 202011354059.2

(51) Int. Cl. H01J 37/32

(52) U.S. Cl. CPC H01J 37/32862; H01J 2237/335; H01J 2237/334; H01J 37/32449

(57) ABSTRACT

The present application makes public a method of processing an etching apparatus, which includes a preprocess, repeatedly introducing plasma containing oxygen free radicals and hydrogen free radicals into a reaction chamber of the etching apparatus to remove vapors from the reaction chamber and Si—C bonds from surface of the reaction chamber; and an ashing process, placing a non-product wafer having photoresist at surface thereof into the reaction chamber, treating the photoresist with plasma containing oxygen free radicals to dissociate the photoresist, and removing Si—OH bonds from the surface of the reaction chamber, dissociated products being attachable onto the surface of the reaction chamber.

### CROSS-REFERENCE TO RELATED APPLICATION

The present application is a continuation of International Patent Application No. PCT/CN2021/096156, filed on May 26, 2021, which claims the right of priority to Chinese Patent Application No. 202011354059.2, filed on Nov. 27, 2020. The entire contents of the aforementioned patent applications are herein incorporated by reference.

### TECHNICAL FIELD

The present application relates to the field of integrated circuits, and more particularly to a method of processing of an etching apparatus.

### BACKGROUND

In order to prolong the service life and to enhance the manufacturing performance of the etching apparatus, regular maintenance is usually carried out on the apparatus.

However, it is generally found that at the end of the processing process of the etching apparatus and at the apparatus-test operation (in which are tested the etching rate of the apparatus and the number of particles) before the apparatus is used again that the number of particles inside the reaction chamber is usually unduly high, and that the time and number of apparatus shutdowns are increased.

Therefore, how to reduce the number of particles inside the etching apparatus, and how to reduce the time and number of apparatus shutdowns are problems to be urgently solved at present.

### SUMMARY

According to one aspect of the present application, a method of processing an etching apparatus is provided, and the method comprises the following steps:

preprocess: repeatedly introducing plasma containing oxygen free radicals and hydrogen free radicals into a reaction chamber of the etching apparatus to remove vapors from the reaction chamber and Si—C bonds from surface of the reaction chamber;

ashing process: placing a non-product wafer having photoresist at surface thereof into the reaction chamber, treating the photoresist with plasma containing oxygen free radicals to dissociate the photoresist, and removing Si—OH bonds from the surface of the reaction chamber, dissociated products being attachable onto the surface of the reaction chamber.

### BRIEF DESCRIPTION OF THE DRAWINGS

The aforementioned and other objectives, features and advantages of the present application will be more lucid and clear through the following description of the embodiments of the present application with reference to the accompanying drawings, in which

FIG. 1 is a diagram schematically illustrating the chemical bonds at the surface of a reaction chamber of the etching apparatus;

FIG. 2 is a diagram schematically illustrating the steps of the method of processing an etching apparatus according to one embodiment of the present application;

FIG. 3A is a diagram schematically illustrating dissociated products of the photoresist being NOT attached onto apertures on the surface of a baffle part in one embodiment of the present application;

FIG. 3B is a diagram schematically illustrating dissociated products of the photoresist being attached onto apertures on the surface of a baffle part in one embodiment of the present application;

FIG. 4 is a diagram schematically illustrating the chemical bonds at the surface of a reaction chamber of the etching apparatus after partial Si—C bonds are removed from the surface of the reaction chamber on the basis of FIG. 1;

FIG. 5 is a diagram schematically illustrating the steps of the method of processing an etching apparatus according to the second embodiment of the present application;

FIG. 6 is a diagram schematically illustrating the chemical bonds at the surface of a reaction chamber of the etching apparatus after Si—C bonds are removed from the surface of the reaction chamber on the basis of FIG. 4; and

FIG. 7 is a diagram schematically illustrating the chemical bonds at the surface of a reaction chamber of the etching apparatus after Si—OH bonds are removed from the surface of the reaction chamber on the basis of FIG. 6.

### DETAILED DESCRIPTION

In order to make the objectives, technical solutions and advantages of the present application more lucid and clear, the present application is described in greater detail below with reference to the specific embodiments in combination with the accompanying drawings. However, as should be understood, the description is merely exemplary in nature, rather than restrictive to the present application. In addition, publicly known structures and technologies are not mentioned in the following description to avoid unnecessary confusion with the conception of the present application.

In the semiconductor fabricating technique, such processes as the photolithography process are usually performed on the photoresist apparatus. The photolithography process is carried out by forming a photoresist layer on the medium or metal film layer of the semiconductor substrate, and transferring patterns on a mask onto the photoresist layer through exposure and development techniques; the semiconductor substrate with photoresist patterns on it is thereafter transferred onto an etching or ion implanting equipment for etching or doping, and the photoresist layer is subsequently removed.

In order to prolong the service life of the photoresist apparatus and to enhance the manufacturing performance of the photoresist apparatus, regular maintenance is usually carried out on the apparatus, for instance, to keep the photoresist apparatus in a good state quarterly, half-yearly or yearly. Specifically speaking, during such maintenance, the parts inside the chamber of the photoresist apparatus are cleaned with a piece of water-soaked dust-free cloth. For example, adaptor and baffle parts of the chamber, the chamber wall and the heat chuck are cleaned to remove resultant foreign matters attached to the chamber and generated in the photoresist manufacturing process. After the cleaning operation is performed and before the photoresist apparatus is used again, it is necessary to remove vapors inside the reaction chamber. The usual removing method is to introduce plasma into the reaction chamber to carry away the vapors inside the chamber.

However, as found by the inventor through research, during the apparatus-test operation (in which are tested the etching rate of the apparatus and the number of particles) before the apparatus is used again, the number of particles in the reaction chamber is unduly high due to the fact that, in the step of the method for introducing plasma to remove vapors from the reaction chamber, since the plasma consists of ions, electrons and unionized neutral particles, the plasma exhibits a neutral matter state as a whole, and the plasma will bind with the surface of the reaction chamber, such as the surfaces of baffle parts that contain C/Si/Al elements etc., and with water (H₂O) in the atmosphere, to form irregular links. During the subsequent apparatus-test operation (in which are tested the etching rate of the apparatus and the number of particles) before the apparatus is used again, these links would be broken, whereby some particles (whose components include Si and C) would fall off above the test wafer, so that the number of particles is unduly high during particle test count, and the time and number of shutdowns of the apparatus are increased.

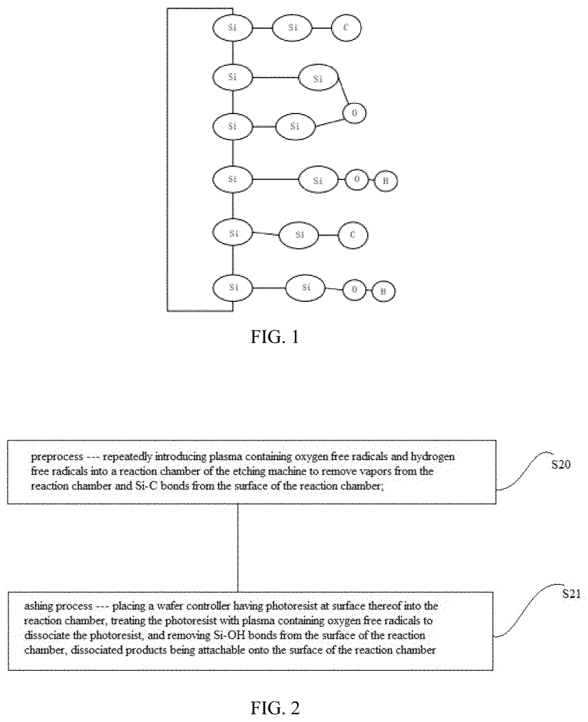

By way of example, please refer to FIG. 1, which is a diagram schematically illustrating the chemical bonds at the surface of a reaction chamber of the etching apparatus, Si—C bonds and Si—OH bonds are present at the sidewall surface of a baffle part, when the reaction chamber is introduced with plasma, the plasma would bind with the Si—C bonds, Si—OH bonds and water in the atmosphere to form irregular links. During the subsequent apparatus-test operation before the apparatus is used again, these links would be broken, whereby some particles would fall off above the test wafer, so that the number of particles is unduly high during particle test count, and the time and number of shutdowns of the apparatus are increased.

Accordingly, the present application provides a method of processing an etching apparatus capable of preventing the plasma from binding with the surface of the reaction chamber to form irregular links, so as to avoid the circumstance in which the number of particles is unduly high in the subsequent apparatus-test operation, and greatly reduce the time and number of shutdowns of the apparatus.

FIG. 2 is a diagram schematically illustrating the steps of the method of processing an etching apparatus according to one embodiment of the present application. Please refer to FIG. 2, the method of processing an etching apparatus according to the present application comprises the following steps:

Step S20: preprocess: repeatedly introducing plasma containing oxygen free radicals and hydrogen free radicals into a reaction chamber of the etching apparatus to remove vapors from the reaction chamber and Si—C bonds from the surface of the reaction chamber.

In this step, plasma is repeatedly introduced into the reaction chamber of the etching apparatus to remove vapors from the reaction chamber. Introduction of plasma into the reaction chamber can remove vapors from the reaction chamber, because the reaction chamber rests in a high-temperature state (250° C. for instance) when plasma is introduced thereto, and vapors always remain in the gaseous state, and the reaction chamber is continuously evacuated, so the vapors can be smoothly evacuated out of the reaction chamber under the high-temperature state.

In the various embodiments of the present application, the surface of the reaction chamber includes the surfaces of adaptor and baffle parts, chamber wall, and the surface of the heat chuck of the reaction chamber that are passed by the plasma when plasma reaction is performed.

In an optional embodiment, the plasma repeatedly introduced into the reaction chamber of the etching apparatus is plasma that contains oxygen free radicals and hydrogen free radicals, so as to remove partial Si—C bonds from the surface of the reaction chamber.

Introduction of plasma containing oxygen free radicals and hydrogen free radicals into the reaction chamber can remove partial Si—C bonds from the inner wall of the reaction chamber, because the oxygen free radicals and hydrogen free radicals in the plasma will bind with the Si—C bonds on the inner wall of the reaction chamber, to form silicon oxide attached onto the surface of the reaction chamber and gaseous hydrocarbon drifting away in the reaction chamber, so as to enable removal of Si—C bonds from the surface of the reaction chamber. The reaction formula is as follows:

SiCₓ+O*+H*→1/2SiO₂+1/2SiOH+CₓH₃ₓ

in which SiCₓ stands for the Si—C bonds at the surface of the reaction chamber, O* stands for the oxygen free radicals in the plasma, and H* stands for the hydrogen free radicals in the plasma.

In an optional embodiment, source gas of plasma reaction is mixed gas of O₂ with H₂N₂. O₂ supplies for the oxygen free radicals, and the mixed gas of H₂N₂ supplies for the hydrogen free radicals. In the mixed gas of O₂ with H₂N₂, a volume ratio of H₂N₂ is 5%-15%. If the volume ratio of the mixed gas of H₂N₂ is relatively higher, the number of oxygen free radicals will be affected, thus leading to deficiency in the oxygen free radicals.

In an optional embodiment, in the mixed gas of H₂N₂, H₂ is a reaction gas, and has a volume ratio of 1%-10%, while N₂ is a carrier, and has a volume ratio of 90%-99%. In other embodiments of the present application, the ratios of H₂ and N₂ in the mixed gas of H₂N₂ can also be other numerical values. As should be noted, the ratios of gases mentioned in the present application all indicate the volume ratios of the gases.

In an optional embodiment, the number of times to introduce plasma containing oxygen free radicals and hydrogen free radicals into the reaction chamber of the photoresist etching apparatus can be set according to specific circumstances of the reaction chamber. For instance, for a reaction chamber with a relatively large dimension, the number of times to introduce plasma containing oxygen free radicals and hydrogen free radicals should be increased, so as to ensure that vapors will be completely removed from the reaction chamber. For a reaction chamber with a relatively small dimension, the number of times to introduce plasma containing oxygen free radicals and hydrogen free radicals should be decreased, so as to reduce consumption of plasma and save production cost at the same time of ensuring that vapors will be completely removed from the reaction chamber.

In an optional embodiment, in the step of preprocess, the pressure in the reaction chamber is 1-2 torr. That is to say, when plasma is repeatedly introduced into the reaction chamber of the etching apparatus in Step S20, the reaction chamber maintains a high-pressure state, as the high pressure strengthens the function of the free radicals of the plasma and enhances the reaction efficiency.

Step S21: ashing process: placing a non-product wafer having photoresist at surface thereof into the reaction chamber, treating the photoresist with plasma containing oxygen free radicals to dissociate the photoresist, and removing Si—OH bonds from the surface of the reaction chamber, dissociated products being attachable onto the surface of the reaction chamber.

In this step, the photoresist (namely a photosensitizer) on the non-product wafer can be chemically reacted with oxygen free radicals, and generate volatile byproducts such as CO₂ etc. These byproducts are attachable into apertures at the surface of the baffle part and the inner wall of the reaction chamber, to make the surface of the baffle part and the inner wall of the reaction chamber more smooth, thereby further preventing oxygen free radicals from attaching in the apertures of the baffle part and the inner wall of the reaction chamber, reducing loss of the oxygen free radicals, and enhancing reaction efficiency.

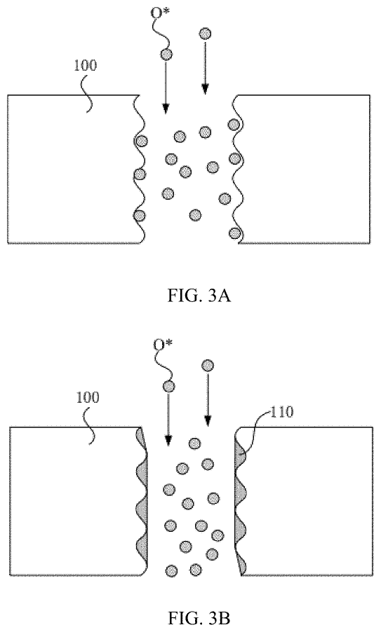

Specifically speaking, the surface of a baffle part is taken for example, FIG. 3A is a diagram schematically illustrating dissociated products of the photoresist being NOT attached onto apertures on the surface of a baffle part 100, and FIG. 3B is a diagram schematically illustrating dissociated products of the photoresist being attached onto apertures on the surface of the baffle part 100. Referring to FIG. 3A, if there is no attachment of dissociated products of the photoresist in the plasma passage of the baffle part 100, the surface of the baffle part 100 has apertures and is not smooth, when the plasma passes therethrough, oxygen free radicals will attach in these apertures, thereby leading to loss of the oxygen free radicals. Referring to FIG. 3B, after associated products 110 of the photoresist attach in the apertures at the surface of the baffle part 100, the apertures at the surface of the baffle part 100 are filled by the dissociated products of the photoresist, when the plasma passes therethrough, it will not attach in the apertures at the surface of the baffle part 100, thereby reducing loss of oxygen free radicals, and enhancing reaction efficiency.

In this step, introduction of plasma containing oxygen free radicals into the reaction chamber can remove Si—OH bonds from the inner wall of the reaction chamber. The plasma can remove Si—OH bonds from the inner wall of the reaction chamber, because oxygen free radicals in the plasma will bind with the Si—OH bonds to form silicon oxide attached to the surface of the reaction chamber and water molecules drifting away in the reaction chamber, thereby enabling removal of Si—OH bonds from the surface of the reaction chamber. The reaction formula is as follows:

SiOH+3/2O*→SiO₂+1/2H₂O

in which SiOH stands for the Si—OH bonds at the surface of the reaction chamber, and O* stands for the oxygen free radicals in the plasma.

In an optional embodiment, in the step of ashing process, source gas of plasma reaction is mixed gas of O₂ with N₂. The N₂ can enhance dissociation degree of oxygen, produce more oxygen free radicals, avoid recombination of the oxygen free radicals, and reduce loss of the oxygen free radicals.

In an optional embodiment, in the mixed gas of O₂ with N₂, the volume ratio of N₂ is 5%-15%.

In an optional embodiment, in the step of ashing process, the pressure in the reaction chamber is 1-2 torr. That is to say, when photoresist is treated with plasma containing oxygen free radicals in Step S21, the reaction chamber maintains a high-pressure state, as the high pressure strengthens the function of the free radicals of the plasma and enhances the reaction efficiency.

In an optional embodiment, in the ashing process is further included a step of heating the non-product wafer having photoresist, so as to quicken dissociation of the photoresist. In this embodiment, the temperature for heating the non-product wafer having photoresist is greater than 130° C., so as to quickly and effectively dissociate the photoresist.

In an optional embodiment, this step can be performed in the same and single reaction chamber by sequentially using plural non-product wafer having photoresist, so as to enhance the smoothness of the surface of the reaction chamber, and to further reduce attachment of oxygen free radicals.

In an optional embodiment, the number of non-product wafer used in the step of ashing process is 100-200, so as to ensure that the surface of the reaction chamber is completely attached by the dissociated products of plasma, to thereby further avoid attachment of oxygen free radicals.

In an optional embodiment, further included is a step of checking leakage of the reaction chamber before the step of preprocess, and still further included is a step of testing number of particles of the reaction chamber after the step of ashing process.

The method of processing an etching apparatus according to the present application can convert the chemical bonds on the surface of the reaction chamber into stable Si—O bonds, thus essentially prevent binding of the plasma with chemical bonds at the inner wall and surface of the reaction chamber, thereby avoid unduly high number of particles in the subsequent apparatus-test operation, and greatly reduce the time and number of shutdowns of the etching apparatus.

As found by the inventor, in the step of preprocess (namely Step S20), the Si—C bonds at the surface of the reaction chamber are not entirely removed, but are merely partially removed. The reason thereof lies in the fact that, since the surface of the reaction chamber has apertures, when plasma passes through the surface of the chamber, oxygen free radicals and hydrogen free radicals will attach in the apertures, the number of free radicals is reduced, while vapors are not entirely removed, this leads to reduction in the reaction rate, and finally possibly leads to incomplete removal, namely partial removal, of Si—C bonds from the surface of the reaction chamber.

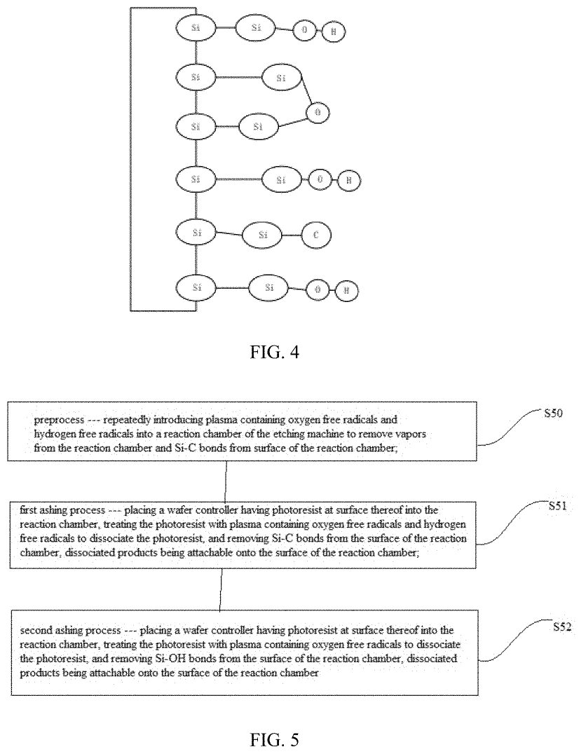

FIG. 4 is a diagram schematically illustrating the chemical bonds at the surface of a reaction chamber of the etching apparatus after partial Si—C bonds are removed from the surface of the reaction chamber on the basis of FIG. 1. As can be seen, Si—C bonds are partially removed from the surface of the reaction chamber after the above reaction is performed.

Accordingly, the present application further provides a second embodiment, which differs from the first embodiment in dividing the ashing process into two steps. For specifics, refer to FIG. 5, which is a diagram schematically illustrating the steps of the method of processing an etching apparatus according to the second embodiment of the present application. In this embodiment, the method of processing an etching apparatus according to the present application comprises the following steps.

Step S50: preprocess: repeatedly introducing plasma containing oxygen free radicals and hydrogen free radicals into a reaction chamber of the etching apparatus to remove vapors from the reaction chamber and Si—C bonds from surface of the reaction chamber. This step is identical to Step S20, so it is not repetitively described in this context.

After Step S50 is executed, Si—C bonds at the surface of the reaction chamber might not be completely removed, but are merely partially removed. Therefore, in order to completely remove the Si—C bonds from the surface of the reaction chamber, Step S51 is executed after Step S50, so as to completely remove the Si—C bonds from the surface of the reaction chamber.

Step S51: first ashing process: placing the non-product wafer having photoresist at surface thereof into the reaction chamber, treating the photoresist with plasma containing oxygen free radicals and hydrogen free radicals to dissociate the photoresist, and removing Si—C bonds from the surface of the reaction chamber, dissociated products being attachable onto the surface of the reaction chamber.

In this step, the oxygen free radicals and hydrogen free radicals in the plasma will bind with the Si—C bonds on the inner wall of the reaction chamber, to form silicon oxide attached onto the surface of the reaction chamber and gaseous hydrocarbon drifting away in the reaction chamber, so as to enable removal of Si—C bonds from the surface of the reaction chamber. The reaction formula is as follows:

SiCₓ+O*+H*→1/2SiO₂+1/2SiOH+CₓH₃ₓ

in which SiCₓ stands for the Si—C bonds at the surface of the reaction chamber, O* stands for the oxygen free radicals in the plasma, and H* stands for the hydrogen free radicals in the plasma.

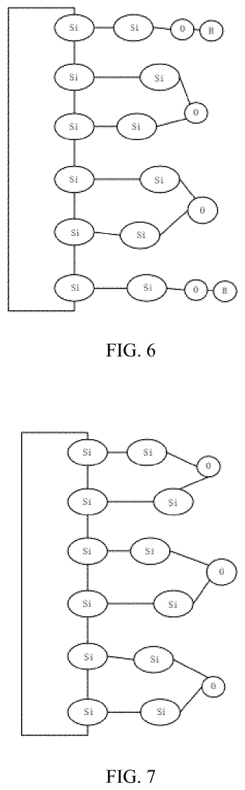

FIG. 6 is a diagram schematically illustrating the chemical bonds at the surface of a reaction chamber of the etching apparatus after Si—C bonds are removed from the surface of the reaction chamber on the basis of FIG. 4. After Step S50 is executed for completion, vapors in the reaction chamber are completely removed, so there will be no influence of vapors in the execution of Step S51. Therefore, after Step S51 is executed for completion, Si—C bonds remaining at the surface of the reaction chamber are completely removed.

In an optional embodiment, in this step, source gas of plasma reaction is mixed gas of O₂ with H₂N₂. O₂ supplies for the oxygen free radicals, and the mixed gas of H₂N₂ supplies for the hydrogen free radicals. In the mixed gas of O₂ with H₂N₂, the volume ratio of H₂N₂ is 5%-15%. If the volume ratio of the mixed gas of H₂N₂ is relatively higher, the number of oxygen free radicals will be affected, thus leading to deficiency in the oxygen free radicals. Moreover, in the mixed gas of H₂N₂, H₂ is a reaction gas, and has a volume ratio of 1%-10%, while N₂ is a carrier, and has a volume ratio of 90%-99%. In other embodiments of the present application, the volume ratios of H₂ and N₂ in the mixed gas of H₂N₂ can also be other numerical values.

In an optional embodiment, in the step of first ashing process, the pressure in the reaction chamber is 1-2 torr. That is to say, when the photoresist is treated with plasma containing oxygen free radicals and hydrogen free radicals in Step S21, the reaction chamber maintains a high-pressure state, as the high pressure strengthens the function of the oxygen free radicals and hydrogen free radicals, and enhances the reaction efficiency.

In this embodiment, the first ashing process lasts for 0.5-1.5 min, so as to ensure complete removal of the Si—C bonds.

In this step, the photoresist (namely a photosensitizer) on the non-product wafer can be chemically reacted with oxygen free radicals, and generate volatile byproducts such as CO₂ etc. These byproducts are attachable into apertures at the surface of the reaction chamber, to make the surface of the reaction chamber smoother, thereby preventing oxygen free radicals from attaching in the apertures on the surface the reaction chamber, reducing loss of the oxygen free radicals, and enhancing reaction efficiency.

In an optional embodiment, in the first ashing process is further included a step of heating the non-product wafer having photoresist, so as to quicken dissociation of the photoresist. In this embodiment, the temperature for heating the non-product wafer having photoresist is greater than 130° C., so as to quickly and effectively dissociate the photoresist.

In an optional embodiment, this step can be performed in the same and single reaction chamber by sequentially using plural non-product wafer having photoresist, so as to further enhance the amount of the attaching dissociated products of the photoresist.

In an optional embodiment, the number of non-product wafer used in the step of first ashing process is 100-200, so as to ensure that the surface of the reaction chamber is completely attached by the dissociated products of plasma, to thereby further avoid attachment of oxygen free radicals.

After Step S51 is executed for completion, Si—OH bonds are present on the surface of the reaction chamber of the etching apparatus, the Si—OH bonds include the original bonds on the surface of the reaction chamber, and also include bonds produced by reaction of the plasma with the Si—C bonds on the surface of the reaction chamber, so Step S52 is executed after Step S51 to remove the Si—OH bonds.

Refer further to FIG. 5, Step S52: second ashing process: placing the non-product wafer having photoresist at surface thereof into the reaction chamber, treating the photoresist with plasma containing oxygen free radicals to dissociate the photoresist, and removing Si—OH bonds from the surface of the reaction chamber, dissociated products being attachable onto the surface of the reaction chamber.

In this step, the photoresist (namely a photosensitizer) on the non-product wafer can be chemically reacted with oxygen free radicals, and generate volatile byproducts such as CO₂ etc. These byproducts are attachable into apertures at the surface of the baffle part and the inner wall of the reaction chamber, to make the surface of the baffle part and the inner wall of the reaction chamber smoother, thereby further preventing oxygen free radicals from attaching in the apertures of the baffle part and the inner wall of the reaction chamber, reducing loss of the oxygen free radicals, and enhancing reaction efficiency.

In this step, introduction of plasma containing oxygen free radicals into the reaction chamber can remove Si—OH bonds from the inner wall of the reaction chamber. The plasma can remove Si—OH bonds from the inner wall of the reaction chamber, because oxygen free radicals in the plasma will bind with the Si—OH bonds to form silicon oxide attached to the surface of the reaction chamber and water molecules drifting away in the reaction chamber, thereby enabling removal of Si—OH bonds from the surface of the reaction chamber. The reaction formula is as follows:

SiOH+3/2O**SiO₂+1/2H₂O

in which SiOH stands for the Si—OH bonds at the surface of the reaction chamber, and O* stands for the oxygen free radicals in the plasma.

FIG. 7 is a diagram schematically illustrating the chemical bonds at the surface of a reaction chamber of the etching apparatus after Si—OH bonds are removed from the surface of the reaction chamber on the basis of FIG. 6. As can be seen, Si—OH bonds are removed from the surface of the reaction chamber after the above reaction is performed, and Si—OH bonds and Si—C bonds are no longer present on the surface of the reaction chamber of the etching apparatus, while only stable Si—O bonds are present there. That is to say, a thin layer of silicon oxide is formed at the surface of the reaction chamber. Since the Si—O bonds are quite stable, they would not bind with the plasma to form any link, and this essentially prevents the generation of particles, and there would not be the circumstance in which subsequent particle test count would show a relatively high number of particles.

In an optional embodiment, in the step of ashing process, source gas of plasma reaction is mixed gas of O₂ with N₂. The N₂ can enhance dissociation degree of oxygen, produce more oxygen free radicals, avoid recombination of the oxygen free radicals, and reduce loss of the oxygen free radicals.

In an optional embodiment, in the mixed gas of O₂ with N₂, the volume ratio of N₂ is 5%-15%.

In an optional embodiment, in the step of second ashing process, the pressure in the reaction chamber is 1-2 torr. That is to say, when photoresist is treated with plasma containing oxygen free radicals in Step S52, the reaction chamber maintains a high-pressure state, as the high pressure strengthens the function of the free radicals of the plasma and enhances the reaction efficiency.

In an optional embodiment, in the second ashing process is further included a step of heating the non-product wafer having photoresist, so as to quicken dissociation of the photoresist. In this embodiment, the temperature for heating the non-product wafer having photoresist is greater than 130° C., so as to quickly and effectively dissociate the photoresist.

In this step, the non-product wafer having photoresist can be replaced, so as to perform operation on the new non-product wafer. The second ashing process lasts for 0.5-1.5 min, so as to ensure complete removal of the Si—OH bonds, to thereby form stable Si—O bonds at the surface of the reaction chamber.

In an optional embodiment, this step can be performed in the same and single reaction chamber by sequentially using plural non-product wafer having photoresist, so as to enhance the smoothness of the surface of the reaction chamber, and to further reduce attachment of oxygen free radicals.

In an optional embodiment, the number of non-product wafer used in the step of second ashing process is 100-200, so as to ensure that the surface of the reaction chamber is completely attached by the dissociated products of plasma, to thereby further avoid attachment of oxygen free radicals.

In the second embodiment, in the step of ashing process is further included a step of performing ashing treatment on the photoresist with plasma containing oxygen free radicals and hydrogen free radicals, so as to completely remove the Si—C bonds from the surface of the reaction chamber, to further avoid the generation of particles.

An example is taken below to describe the specific mode of executing the method of processing an etching apparatus according to the present application.

Step 1: the photoresist etching apparatus performing plural times (200, for instance) of cleaning processes;

Step 2: preprocess: introducing plasma containing oxygen free radicals and hydrogen free radicals repeatedly (for 60 times, for instance) into the reaction chamber of the photoresist etching apparatus, source gas of the plasma being the mixed gas of O₂ with H₂N₂, wherein the reaction chamber is in a high-pressure state and its pressure is 1-2 torr while plasma reaction is carried out.

Step 3: placing the wafer having photoresist at surface thereof in the reaction chamber, and treating the photoresist with plasma containing oxygen free radicals to dissociate the photoresist, dissociated products being attachable onto the surface of the reaction. In this step, 150 non-product wafer having photoresist are used to sequentially react through the reaction chamber, wherein source gas of the plasma is the mixed gas of O₂ with H₂N₂. The reaction chamber is in a high-pressure state and its pressure is 1-2 torr while plasma reaction is carried out.

Step 4: placing the wafer having photoresist at surface thereof in the reaction chamber, and treating the photoresist with plasma containing oxygen free radicals to dissociate the photoresist, dissociated products being attachable onto the surface of the reaction. In this step, 150 non-product wafer having photoresist are used to sequentially react through the reaction chamber, wherein source gas of the plasma is the mixed gas of O₂ with N₂. The reaction chamber is in a high-pressure state and its pressure is 1-2 torr while plasma reaction is carried out.

Step 5: performing apparatus-test operation.

After the foregoing steps and the apparatus-test operation, the number of particles in the photoresist etching apparatus will be within an allowable range, and there would not be the case of unduly high number, thereby greatly reducing the time and number of shutdowns of the photoresist etching apparatus.

As should be understood, the foregoing specific embodiments of the present application are meant merely to exemplarily describe or explain the principle of the present application, but do not constitute any restriction to the present application. Accordingly, any modification, equivalent substitution and improvement makeable without departing from the spirit and scope of the present application shall all be contained within the protection scope of the present application. In addition, the Claims attached to the present application are meant to cover all variant and modified embodiments falling within the scope and boundary, or equivalent modes of the scope and boundary of the attached claims.

What is claimed is:

1. A method of processing an etching apparatus, comprising the following steps:
preprocess, repeatedly introducing plasma containing oxygen free radicals and hydrogen free radicals into a reaction chamber of the etching apparatus to remove vapors from the reaction chamber and Si—C bonds from surface of the reaction chamber; and
ashing process, placing a non-product wafer having photoresist at surface thereof into the reaction chamber, treating the photoresist with plasma containing oxygen free radicals to dissociate the photoresist, and removing Si—OH bonds from the surface of the reaction chamber, dissociated products being attachable onto the surface of the reaction chamber.

2. The method of processing an etching apparatus according to claim 1, wherein in the step of preprocess, a source gas of plasma reaction is a mixed gas of O₂ with H₂N₂.

3. The method of processing an etching apparatus according to claim 2, wherein in the mixed gas of O₂ with H₂N₂, a volume ratio of H₂N₂ is 5%-15%.

4. The method of processing an etching apparatus according to claim 2, wherein in the H₂N₂, a volume ratio of H₂ is 1%-10%, and a volume ratio of N₂ is 90%-99%.

5. The method of processing an etching apparatus according to claim 1, wherein in the step of preprocess, pressure in the reaction chamber is 1-2 torr.

6. The method of processing an etching apparatus according to claim 1, wherein in the step of ashing process, the source gas of plasma reaction is the mixed gas of O₂ with N₂.

7. The method of processing an etching apparatus according to claim 6, wherein in the mixed gas of O₂ with N₂, a volume ratio of N₂ is 5%-15%.

8. The method of processing an etching apparatus according to claim 1, wherein the step of ashing process further comprises:
first ashing process: placing the non-product wafer having photoresist at surface thereof into the reaction chamber, treating the photoresist with plasma containing oxygen free radicals and hydrogen free radicals to dissociate the photoresist, and removing Si—C bonds from the surface of the reaction chamber, dissociated products being attachable onto the surface of the reaction chamber; and
second ashing process: placing the non-product wafer having photoresist at surface thereof into the reaction chamber, treating the photoresist with plasma containing oxygen free radicals to dissociate the photoresist, and removing Si—OH bonds from the surface of the reaction chamber, dissociated products being attachable onto the surface of the reaction chamber.

9. The method of processing an etching apparatus according to claim 8, wherein in the step(s) of first ashing process and/or second ashing process, pressure in the reaction chamber is 1-2 torr.

10. The method of processing an etching apparatus according to claim 8, wherein the first ashing process lasts for 0.5-1.5 min, and the second ashing process lasts for 0.5-1.5 min.

11. The method of processing an etching apparatus according to claim 8, wherein number of the non-product wafer used in the step(s) of first ashing process and/or second ashing process is 100-200.

12. The method of processing an etching apparatus according to claim 8, wherein in the step(s) of first ashing process and/or second ashing process is further included a step of heating the non-product wafer having photoresist.

13. The method of processing an etching apparatus according to claim 12, wherein heating temperature is greater than 130 degrees Celsius.

14. The method of processing an etching apparatus according to claim 1, further comprising a step of checking leakage of the reaction chamber before the step of preprocess.

15. The method of processing an etching apparatus according to claim 1, further comprising a step of testing number of particles of the reaction chamber after the step of ashing process.
